(19) United States
(12) Patent Application Publication
(10) Pub. No.: US 2010/0175621 A1
(43) Pub. Date: Jul. 15, 2010

(54) Microwave Plasma Processing Apparatus

(76) Inventors: Koichi Yamazaki, Yamanashi-ken (JP); Masaki Sano, Yamanashi-Ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/223,253

(22) PCT Filed: Jan. 31, 2007
(86) PCT No.: PCT/JP2007/051624

§ 371 Date: Jul. 25, 2008

(30) Foreign Application Priority Data
Jan. 31, 2006 (JP) 2006-023282

(51) Int. Cl. C23C 16/513; B32B 3/00

(52) U.S. Cl. 118/723 AN; 428/141

(57) ABSTRACT

Disclosed is improvement of a quartz-glass top plate to be used as a microwave-transmitting window in a microwave plasma processing apparatus. The surface, facing a substrate W, of the top plate has surface roughness equal to or less than 0.2 μm in arithmetic mean surface roughness Ra. Thereby, generation of particles derived from the quartz glass material constituting the top plate is minimized, even when the top plate is exposed to a severe environment of high electron density and high electron temperature.

### TECHNICAL FIELD

The present invention relates to a microwave plasma processing apparatus used in manufacturing semiconductor devices, and more particularly, to improvement of a top plate that functions as a microwave-transmitting window in a microwave plasma processing apparatus.

### BACKGROUND ART

A plasma process is a technique that allows the surfaces of substrates to be efficiently oxidized, nitrided, or oxynitrided at relatively low substrate temperatures up to several hundred degrees C., by use of plasma-excited active species such as radicals. This technique that has been used in the manufacturing processes for various semiconductor devices. In the manufacture of today's ultrafine-structured semiconductor devices, in particular, this technique has come to occupy unprecedented importance in connection with the formation of so-called high-k gate dielectric films or the formation of low-k interlayer dielectric films.

FIG. 1A shows the configuration of a microwave plasma processing apparatus 10 used for the oxidizing, nitriding, or oxynitriding process in the manufacture of such an ultrafine-structured semiconductor device.

Referring to FIG. 1A, the microwave plasma processing apparatus 10 includes a processing container 11 in which a process space 11A is formed. A substrate mounting table 12 for holding a substrate W to be processed is provided in the process space 11A of the processing container 11. The internal atmosphere of the processing container 11 is evaluated through a space 11B formed around the bottom of the substrate mounting table 12 and an exhaust port 11C by means of an exhaust system 11E via an APC (automatic pressure control) valve 11D.

A heater 12A is provided in the substrate mounting table 12. When electric power is supplied from a power supply 12C via a power supply line 12B, the heater 12A generates heat to heat the substrate W.

A substrate loading/unloading port 11g with a gate valve 11G is formed in the processing container 11. The substrate W is loaded into and unloaded from the processing container 11 via the substrate loading/unloading port 11g.

The upper end of the processing container 11 has an opening at a position corresponding to the substrate W. The opening is airtightly closed by a top plate 13 made of a dielectric material such as quartz glass or a ceramic. A gas ring 14, which has a gas inlet and a large number of nozzle openings communicating with the gas inlet, is provided below the top plate 13 to face the substrate W.

The top plate 13 functions as a microwave-transmitting window. An antenna such as a planar antenna is disposed above the top plate 13. A radial line slot antenna can be used as the planar antenna.

The antenna unit 15 shown in FIG. 1A includes a slot antenna 15C having a plurality of slots 15a, 15b (see FIG. 1B), and a slow-wave plate 15B covering the slot antenna 15C. The slot antenna 15C is provided via the top plate 13 which is formed of a dielectric material and closes the opening formed in the upper part of the processing container 11. Additionally, a conductor cover 15A is disposed to cover the slow-wave plate 15B.

Connected to the antenna unit 15 is a coaxial waveguide 16 composed of an outer waveguide 16A and an inner waveguide 16B. More specifically, the inner waveguide 16B extends through the slow-wave plate 15B and is connected to the center of the slot antenna 15C.

The coaxial waveguide 16 is connected via a mode converter 110A to a waveguide 110B having a rectangle cross section. The waveguide 110B is coupled to a microwave source 112 via an impedance-matching box 111. A microwave generated by the microwave source 112 is supplied to the antenna unit 15 via the rectangular waveguide 110B and the coaxial waveguide 16.

FIGS. 2(A) to 2(C) are diagrams explaining a series of process steps for forming an SiON film on the surface of a silicon substrate 21 using the plasma-processing apparatus 10 shown in FIGS. 1A and 1B.

First, as shown in FIG. 2(A), the silicon substrate 21 is subjected to a DHF (diluted hydrofluoric acid aqueous solution) treatment so that natural oxide films are removed from the surface. Next, as shown in FIG. 2(B), the silicon substrate 21 is introduced into the processing container 11 of the plasma processing apparatus 10. Then, the silicon substrate 21 is subjected to a microwave plasma process under predetermined process conditions using argon (Ar) gas and oxygen gas. Thus, a silicon oxide film 22 having a thickness as small as about 1 nm is formed on the surface of the silicon substrate 21.

Next as shown in FIG. 2(C), in the processing container 11, the silicon substrate 21 is further subjected to a microwave plasma process under predetermined process conditions using Ar gas and nitrogen gas. Thus, the silicon oxide film 22 on the surface of the silicon substrate 21 is converted into an SiON film 22N.

During such film-forming experiments, the present inventors found that if the substrate was processed at a process pressure particularly of 12 Pa (90 mTorr) or less, particles typically from 0.5 to 2.0 μm in diameter appeared on the processed substrate surface.

### DISCLOSURE OF THE INVENTION

The generation of such large-sized particles should be avoided, since it will significantly reduce the manufacturing yield rate of the semiconductor devices. The object of the present invention is to prevent generation of such particles.

Upon inventor's component analysis, it was concluded that these particles were composed primarily of Si and oxygen and were derived from the top plate made of quartz glass. In addition, as a result of researches and experiments, the present inventors reached the conclusion that the above problem can be solved by controlling the surface roughness of the top plate to 0.2 μm or less in arithmetic mean roughness Ra during the manufacture of the top plate. Techniques for appropriately controlling the surface condition of quartz glass parts during the manufacture thereof to reduce the generation of particles in a broader sense are described in literature such as JP2004-123508A, JP10-163180A, JP2002-356346A, and JP2004-296753A. However, the techniques described in those documents differ from the present invention in technical concept.

The present invention has been made based on the above knowledge. Thus, according to a first aspect of the invention, there is provided a microwave plasma processing apparatus, including: a processing container configured to be evacuated and having therein a substrate mounting table to hold a substrate; a top plate made of quartz glass, the top plate being disposed at an upper portion of the processing container so as to face the substrate held on the substrate mounting table; a microwave antenna provided above the top plate; and a gas supply system that supplies a process gas into the processing container; wherein a surface, facing the substrate, of the top plate has surface roughness equal to or less than 0.2 μm in arithmetic mean roughness Ra.

According to a second aspect of the present invention, there is provided a top plate formed of quartz glass for transmitting therethrough microwaves to deliver microwave radiation to an interior of a processing container, wherein a surface of the top plate, which is to be exposed to an interior space of the processing container when the top plate is mounted to the processing container, has surface roughness equal to or less than 0.2 μm in arithmetic mean roughness Ra.

The foregoing surface roughness is preferably 0.13 μm or less in arithmetic mean roughness Ra, and more preferably, 0.1 μm or less.

Fire polishing or mechanical polishing may be employed as a suitable method to achieve the above surface roughness.

### BRIEF DESCRIPTION OF DRAWINGS

FIG. 1A is a schematic sectional view showing the configuration of a conventional microwave plasma processing apparatus;

FIG. 1B is a schematic plan view showing the configuration of a radial line slot antenna used in the conventional microwave plasma processing apparatus of FIG. 1A;

FIGS. 2(A) to 2(C) are diagrams explaining a series of steps taken to form an SiON film on a silicon substrate 21 using the plasma processing apparatus 10 of FIGS. 1A and 1B;

FIG. 3 is a schematic sectional view showing the configuration of a microwave plasma processing apparatus according to the present invention;

FIGS. 4(A) and 4(B) are diagrams showing electron density distribution and electron temperature distribution in the microwave plasma processing apparatus of FIG. 3;

FIGS. 5(A) and 5(B) are graphs that represent relationships of a process pressure with respect to ion energy and electron density, respectively, in the microwave plasma processing apparatus of FIG. 3;

FIG. 6 is a flowchart that explains manufacturing steps relating to a conventional top plate made of quartz glass;

FIGS. 7(A) and 7(B) are surface roughness meter output graphs that represent surface roughness of the quartz-glass top plate manufactured in the manufacturing steps of FIG. 6;

FIG. 8 is a graph that represents changes in the number of particles detected during film-forming experiments with a variety of quartz-glass top plates different in surface roughness;

FIGS. 9(A) to 9(C) are surface roughness meter output graphs that represent surface roughness of top plate samples created by mechanical polishing or fire polishing according to the present invention;

FIGS. 10(A) and 10(B) are copies of optical micrographs which show surface states of quartz-glass top plates;

FIG. 11 is a graph representing a relationship between the surface roughness and particle count of a top plate obtained in the above film-forming experiments: and

FIG. 12 is a graph that shows changes in the particle count of a top plate obtained in the above film-forming experiments.

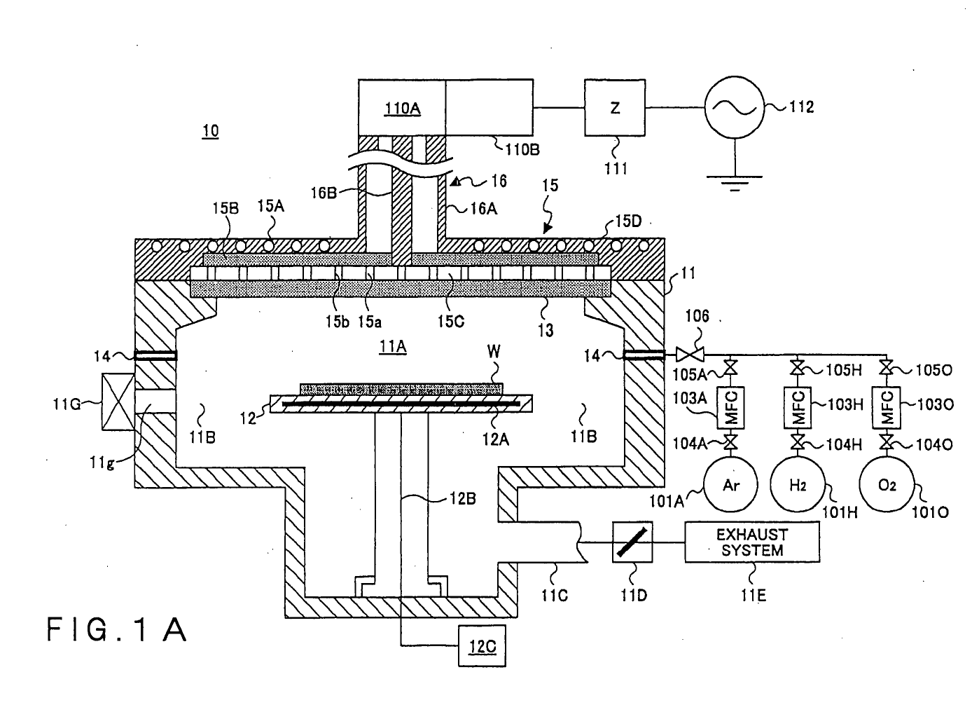

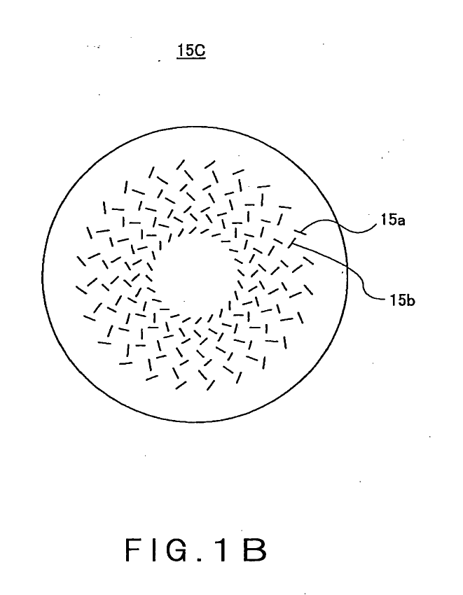

### BEST MODE FOR CARRYING OUT THE INVENTION

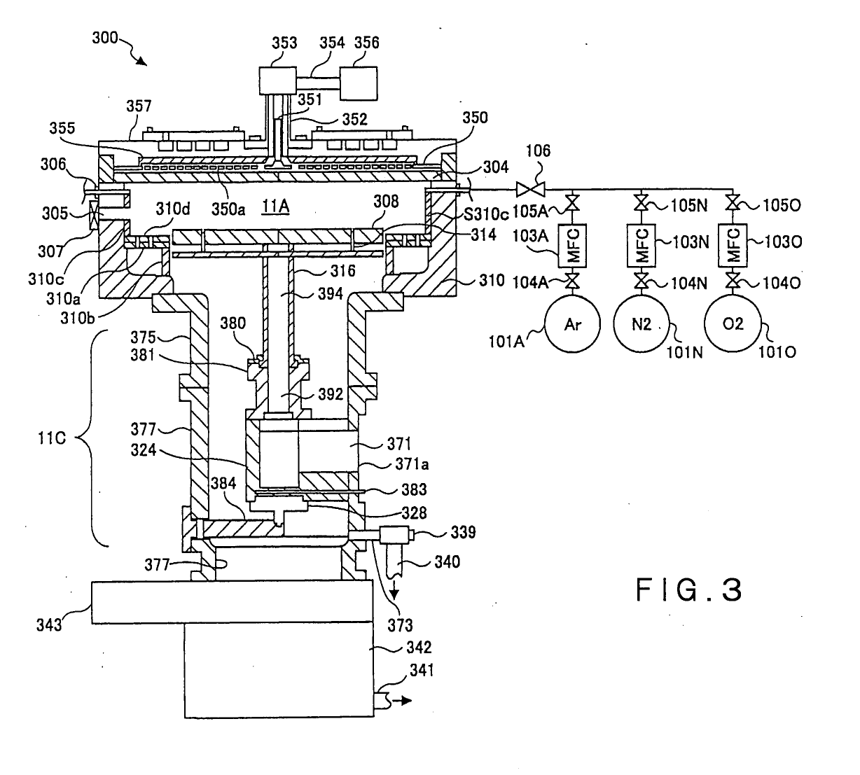

First, the configuration of a plasma processing apparatus, in which a top plate improved in accordance with the present invention is incorporated, will be described with reference to FIG. 3.

The plasma processing apparatus 300 has a processing container 310 of a cylindrical shape whose upper end is opened. The processing container 310 may be of a rectangular shape (e.g., a square). The processing container 310 is formed of a conductor, which may be a metal or an alloy, such as aluminum or stainless steel.

The opening in the upper portion of the processing container 310 is closed by a horizontally-disposed dielectric plate 304 of a disc shape, that is, a top plate. The dielectric plate 304 is installed on a support (not shown) that protrudes inward from a side circumferential wall of the processing container 310. The dielectric plate 304 is formed of quartz or ceramic with a thickness of 10-50 mm, preferably 20-30 mm. A sealing material such as an O-ring is interposed between the aforementioned support (not shown) and the dielectric plate 304 to provide airtight sealing.

A slot antenna 350, which is one type of a planer antenna, is provided above the dielectric plate 304. The slot antenna 350 may be either in close contact with the dielectric plate 304 or spaced therefrom. A microwave generator 356 for generating microwaves of 300 MHz to 30 GHz, for example, 2.45 GHz microwaves is provided. The microwaves generated by the microwave generator 356 are introduced into a microwave mode converter 353 via a rectangular waveguide 354 connected to the microwave generator 356, and then introduced into the slot antenna 350 via a coaxial waveguide 352 connected to the microwave mode converter 353. More specifically, an internal conductor 351, which is disposed in the coaxial waveguide 352 and is formed of an electrically-conductive material, is connected to a central part of the slot antenna 350. An upper face of the slot antenna 350 is covered with a slow-wave plate 355 formed of a dielectric material such as quartz. Furthermore, a cover plate 357 formed of a conductor is disposed over an upper face of the slow-wave plate 355. The cover plate 357 shields the microwaves and also functions as a planar waveguide. The cover plate 357 has a cooling jacket to allow efficient cooling of the slow-wave plate 355, the slot antenna 350 and the dielectric plate 304. Electric power efficiency can be improved by providing an impedance-matching circuit (not shown) midway on the rectangular waveguide 354.

The microwaves that have been supplied via the coaxial waveguide 352 are introduced into the processing container 310 via slots in the slot antenna 350 and the dielectric plate 304 functioning as a microwave-transmitting window. Thus, a high-frequency electromagnetic field is formed in the processing container 310. The slot antenna 350 is isolated from the internal space of the processing container 310 by the dielectric plate 304 and thus is not exposed to plasma generated in the processing container 310.

The processing container 310 has a bottom, to which two exhaust pipes, 375 and 377, are airtightly connected. The two exhaust pipes, 375 and 377, may be integrated into a single exhaust pipe. A turbomolecular pump 342 is connected to a lower end of the exhaust pipe 377 via a valve 343. The valve 343 is a pressure control valve, for example, a vacuum or automatic pressure control (APC) valve. A lower lateral face of the exhaust pipe 377 has a rough exhaust port 373 for rough evacuation of the processing container 310. A vacuum pump (not shown) is connected to the rough exhaust port 373 via a rough vacuum line 340 having a valve 339 mounted thereon. The turbomolecular pump is connected to the vacuum pump via an exhaust line 341.

The interior of the processing container 310 can be set to a desired degree of vacuum, by pre-evacuating with the rough vacuum line 340 and the vacuum pump (not shown), and then evacuating with the turbomolecular pump 342. The sidewall of the processing container 310 is provided with a gas injector 306 for introducing various process gases into the processing container 310. The gas injector 306 may be composed of multiple nozzles, or an annular gas ring having gas holes arranged at regular intervals on its inner surface.

In the illustrated embodiment, a rare gas source 101A for supplying a rare gas such as argon (Ar) gas, a nitrogen gas source 101N, and an oxygen gas source 101O are connected to the gas injector 306 via respective mass flow controllers (MFCs) 103A, 103N, and 103O, respective valves 104A, 104N, and 104O, and a common valve 106. The gas injector 306 has a large number of gas introduction ports 306a arrayed as to surround a mounting table 308. Consequently, Ar gas, nitrogen gas, and oxygen gas or a mixture thereof can be uniformly introduced into the process space 11A of the processing container 310.

Other gas sources for supplying gases such as hydrogen, ammonia, NO, N₂O, and H₂O gases, may be further provided.

The mounting table 308 for placing thereon an object to be processed, e.g., a semiconductor wafer (not shown), is provided inside the processing container 310. A recess, having a diameter slightly greater than the outside diameter of the semiconductor wafer and a depth of about 0.5-1.0 mm, is formed on an upper surface of the mounting table 308 to prevent displacement of the semiconductor wafer. An annular guide ring may be provided outside the mounting area for the semiconductor wafer. If the mounting table 308 has an electrostatic chuck, the aforementioned recess may be omitted, since the semiconductor wafer is retained by electrostatic force. A plurality of (in the illustrated embodiment, three) lifter pins 314 extends through the mounting table 308. The lifter pins 314 are held by a horseshoe-shaped support 314A, and are vertically movable.

A resistance heating element (not shown) is buried in the mounting table 308. Electric power is applied to the resistance heating element to heat the mounting table 308, whereby the wafer is heated. The material forming the mounting table 308 is a ceramic material such as AlN or Al₂O₃.

A lower electrode may be buried in the mounting table 308. In this case, either a high-frequency power supply for applying a high-frequency bias of 450 kHz to 13.65 MHz, or a direct-current power supply for applying a continuous bias may be connected to the lower electrode.

A mounting table fixing part 324 supports the mounting table 308 via a mounting table support 316 and so on. The mounting table fixing part 324 is formed of, for example, a metal such as aluminum, or an alloy thereof; and the mounting table support 316 is formed of, for example, a ceramic material such as AlN. The mounting table 308 and the mounting table support 316 are integrally formed, or bonded together by bonding means such as brazing, so that vacuum seals and fixing screws are not necessary for connecting those parts. The mounting table support 316 has a lower end fixed to a support fixing part 381 via a fixing ring 380 by fixing means such as screws, the support fixing section 381 and the fixing ring 380 each being made of, for example, a metal such as aluminum, or an alloy thereof. Thus, the size of the gap between the upper surface of the mounting table 308 and a lower surface of the dielectric plate 304 is adjustable. The mounting table support 316 and the support fixing part 381 are airtightly sealed with sealing means such as an O-ring (not shown). The support fixing part 381 is airtightly fixed to the mounting table fixing part 324 via sealing means such as an O-ring (not shown). The support fixing part 381 may be omitted, depending on particular sizes of the mounting table 308 and the mounting table support 316.

The mounting table fixing part 324 is airtightly mounted on a side of the exhaust pipe 377 via sealing means such as an O-ring (not shown), by use of fixing means such as screws. More specifically, a lateral portion of the mounting table fixing part 324 is connected to an inner surface of the exhaust pipe 377. A lower portion of the mounting table fixing part 324 is supported by a fixing member 384 that functions as a positioner for positioning the mounting table 308 horizontally via the mounting table fixing part 324 during assembly for maintenance, for example. The fixing member 384 communicates with an opening provided in the exhaust pipe 377, and is fixed to the exhaust pipe 377. The mounting table fixing part 324 is attached to an end of the fixing member 384 via an engagement member 328 provided at the lower portion of the mounting table fixing section 324, so that the mounting table 308 can be easily set horizontal.

The fixing member 384 also functions as a positioning member. The mounting table 308 is positioned when the lower portion of the mounting table fixing part 324 is engaged with an engagement portion provided at the end of the fixing member 384, via the engagement member 328. In the illustrated embodiment, a recess serving as the engagement portion is formed in an upper side of the end of the fixing member 384, and a projection formed on a lower portion of the engagement member 328 is inserted into the recess. The engagement member 328 may be fixed to the engagement portion of the fixing member 384 by using fixing member such as screws. Alternatively, the end of the fixing member 384 may have a hole serving as the engagement portion of the positioning member so that the lower portion of the mounting table fixing part 324 may be inserted into the hole.

The mounting table fixing part 324 internally provided with a space 371 that is opened towards a sidewall of the exhaust pipe 377, and the space 371 communicates with the atmosphere via, an opening 371a provided in a lateral face of the exhaust pipe 377. A space 394 inside the mounting table support 316 communicates with the space 371 via an internal space 392 of the support fixing part 381 and is open to the atmosphere.

Contents such as electrical lines for supplying power to the resistance heating element (not shown) that is buried in the mounting table 308, and electrical lines of a thermocouple for measuring and controlling the temperature of the mounting table 308, are arranged in the internal space of the mounting table fixing part 324. These contents are omitted in FIG. 3. The contents are routed from the opening 371a in the space 371 of the mounting table fixing part 324 through the internal space 394 of the mounting table support 316 and the space 371 to the exterior of the plasma processing apparatus 300.

Inside the lower portion of the mounting table fixing part 324 is buried a cooling water channel 383, into which cooling water can be introduced from the outside of the plasma processing apparatus 300. The cooling water prevents temperature rising of the mounting table fixing part 324 and the support fixing part 381 due to heat transfer from the mounting table 308 via the mounting table support 316 to the mounting table fixing part 324 and the support fixing section 381.

As described above, in the plasma processing apparatus 300, the mounting table 308 is fixed at a plurality of positions to the exhaust pipe 377. In the illustrated embodiment, the mounting table 308 is fixed at a lateral portion and bottom portion of the mounting table fixing part 324 to which the mounting table 308 is attached. The bottom of the mounting table fixing part 324 is fixed to the exhaust pipe 377 via the engagement member 324 and the fixing member 384. The lateral portion of the mounting table fixing part 324 is fixed to the inner lateral surface of the exhaust pipe 377. That is, the mounting table 308 is fixed to the exhaust pipe 377 by the two fixing portions and thus fixed with respect to the processing container 310. When maintenance is performed, the mounting table 308 can be easily placed horizontally, since the mounting table 308, the mounting table support 316, the support fixing part 381 and the mounting table fixing part 324 are positioned by inserting the recess of the engagement member 328 into the projection formed at the end of the fixing member 384.

Inside the processing container 310, a baffle plate 310a made of a metal such as aluminum or stainless steel is disposed around the mounting table 308 to uniformly evacuate the process space 11A within the processing container 310. On the baffle plate 310a, a baffle plate 310d made of a dielectric material such as quartz is provided to prevent contamination. The baffle plate 310a is supported by a baffle plate supporting member 310b. A liner 310c made of quartz or the like may be provided on an inner wall surface of the processing container 310 to protect the inner wall surface. In this way, cleanness of the process space 11A can be maintained, by covering the surface facing the process space 11A of the processing container 310 with the members (310d, 310c) that generate no contamination such as quartz.

Next, formation of a gate oxide film, for example, an SiON film, for an MIS (Metal Insulator Semiconductor) type semiconductor device on a semiconductor wafer will be described as an example of a film forming process using the plasma processing apparatus 300 in one embodiment of the present embodiment. In the plasma processing apparatus 300, the distance between the dielectric plate 304 and the mounting table 308 is prefixed at a predetermined value. First, vacuum evacuation is conducted via the rough vacuum line 340, then after the inside of the processing container 310 has reached a predetermined degree of vacuum, a gate valve 307 is opened to load the semiconductor wafer into a position above the mounting table 308 through a wafer loading/unloading port 305, and the wafer is held by means of the lifter pins 314. The semiconductor wafer thus loaded is already subjected to a cleaning process using diluted hydrofluoric acid (1% HF) solution or the like and has a clean silicon (Si) surface. When the semiconductor wafer is loaded, the lifter pins 314 are lowered to place the loaded wafer on the mounting table 308.

Subsequently, the inside of the processing container 310 is evacuated to a predetermined degree of vacuum, for example, 1 to 133.3 Pa, by the turbomolecular pump 342. With keeping this degree of vacuum, process gases (a plasma gas such as Ar gas, and a reaction gas such as nitrogen gas (in a case of nitriding) and/or oxygen gas (in a case of oxidizing) are uniformly introduced into the processing container 310 through the gas injector 306 while controlling the flow rate of each gas.

Next, with the process gas being introduced into the processing container, a 2.45-GHz high-frequency electromagnetic field is supplied from the microwave-generating power supply unit 356. This high-frequency electromagnetic field propagates in rectangular mode through the rectangular waveguide 354, is converted from rectangular mode into circular mode by the mode converter 353, propagates in circular mode through the circular coaxial waveguide 352, introduced into the slot antenna 350, and radiated from the slots in the slot antenna 350. Further, the high-frequency electromagnetic field passes through the high-dielectric plate 304 and is introduced into the processing container 310 to form an electric field in the processing container 310. This electric field ionizes the process gases, and creates plasma having an electron temperature of 0.5 to 2.0 eV and a density of 10¹¹-10¹³/cm³ in a space above the semiconductor wafer. The semiconductor wafer is subjected to a predetermined process (nitriding process or oxidizing process) uniformly by the plasma.

In a case where an SiON film as an insulating film is formed on a semiconductor wafer, the semiconductor wafer having the silicon oxide film formed thereon is heated at 400° C. by heating the mounting table 308. Under this state, as the process gases, Ar gas and N₂ gas are introduced at flow rates of 500 sccm and 25 sccm, respectively, via the gas injector 306. The rare gas contained in the process gases may be Xe gas or Kr gas in place of the Ar gas. In this way, the surface of the SiO₂ film on the Si substrate is modified into an SiON film by nitriding. To form an SiN film by nitriding directly the semiconductor wafer, i.e., the silicon substrate, the semiconductor wafer may be processed with the plasma of the Ar gas and the nitrogen gas.

Upon completion of such a film-forming process, the lifter pins 314 raises to lift the semiconductor wafer on the mounting table 308, and then the semiconductor wafer is unloaded from the processing container 301 through the wafer loading/unloading port 305.

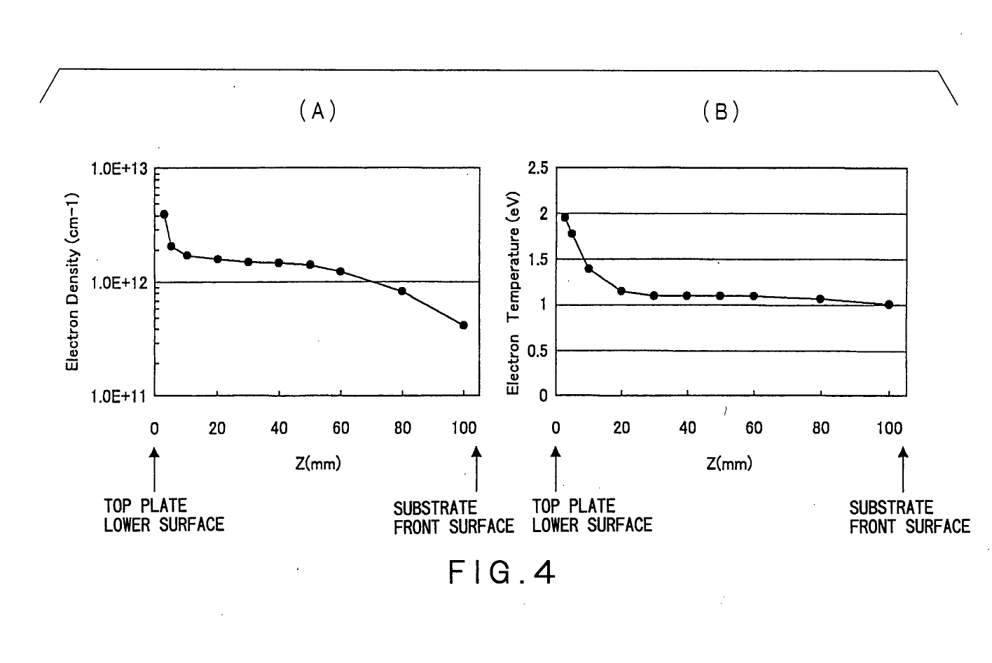

FIGS. 4(A) and 4(B) respectively show electron density distribution and electron temperature distribution in the plasma generated in the process space 11A of the processing container 310 in the plasma processing apparatus 300 of FIG. 3.

As can be seen from FIG. 4(A), plasma having an electron density of an order of 10¹¹ cm⁻³ is formed at a position (i.e., substrate surface position) 100 mm away from the lower surface of the dielectric plate 304, i.e., the top plate. The electron density increases according to the proximity to the dielectric plate 304, and is 2 to 4×10¹² cm⁻³ at a position immediately below the dielectric plate 304.

As can be seen from FIG. 4(B), although the electron temperature in the plasma is substantially 1 eV at the substrate surface position, plasma with a high energy of 1.5 to 2.0 eV is formed immediately below the dielectric plate 304. Abrupt reductions in the electron density and electron temperature at a position about 20 mm below the dielectric plate 304 are due to cutoff effect of the plasma.

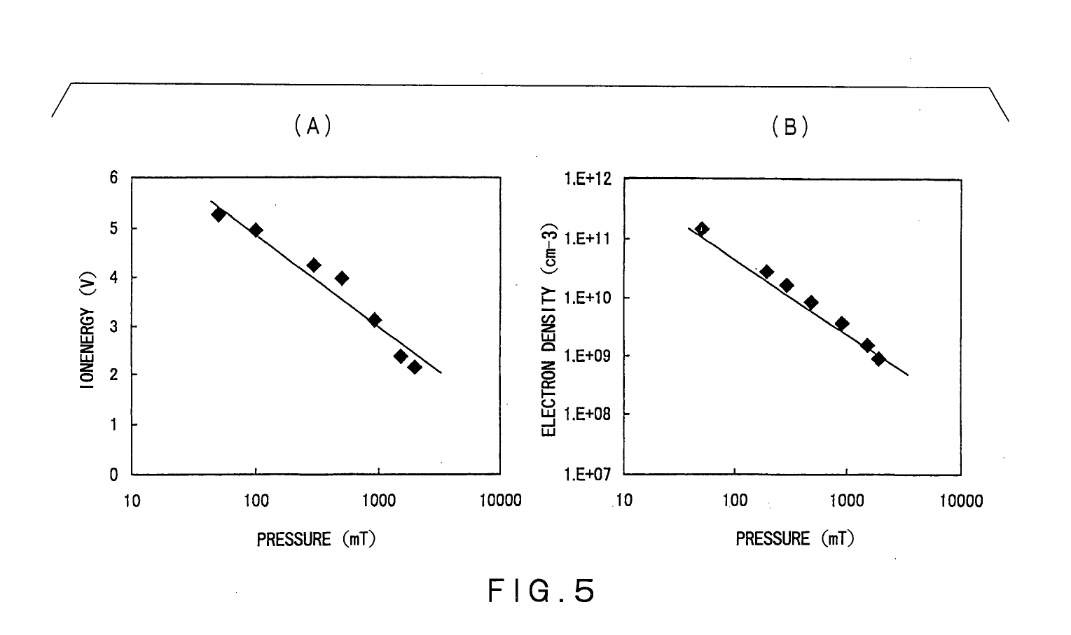

The Process in the microwave plasma processing apparatus 300 of FIG. 3 is characterized in that plasma of a low electron temperature acts on the substrate, whereas the dielectric plate 304 is attacked by large electron energy as described above which is considered to be the cause of generation of particles previously described. In particular, when a plasma process is performed under a low pressure, not only the electron density but also ion energy increases and the lower surface of the dielectric plate 304 is exposed to a severer environment. This can be seen from FIG. 5(A) showing the relationship between the ion energy of the plasma formed in the processing container 310 and the process pressure, and from FIG. 5(B) showing the relationship between the electron temperature of the plasma formed in the processing container 310 and the process pressure. Data shown in FIGS. 5(A) and 5(B) were obtained under the situation where plasma is excited at a microwave power of 2 kW with the flow rates of the Ar gas and the nitrogen gas set to be 1,000 sccm and 40 sccm, respectively. Since the plasma process under a low pressure suppresses re-oxidation of the substrate surface due to oxygen released from the substrate during the process such as a nitriding process, the low-pressure plasma process is very important for forming a high-quality ultra-thin SiN film or SiON film as thin as about 1 nm or less in the equivalent oxide film thickness (EDT) used for gate-insulating films and the like. Therefore, it is very beneficial to provide the dielectric plate 304, or the top plate, that is not damaged even under a low-pressure plasma process.

Next, the quartz-made dielectric plate 304, or the top plate, according to the present invention will be described in detail with reference to the results of experiments that compared the top plate of the present invention with a conventional top plate.

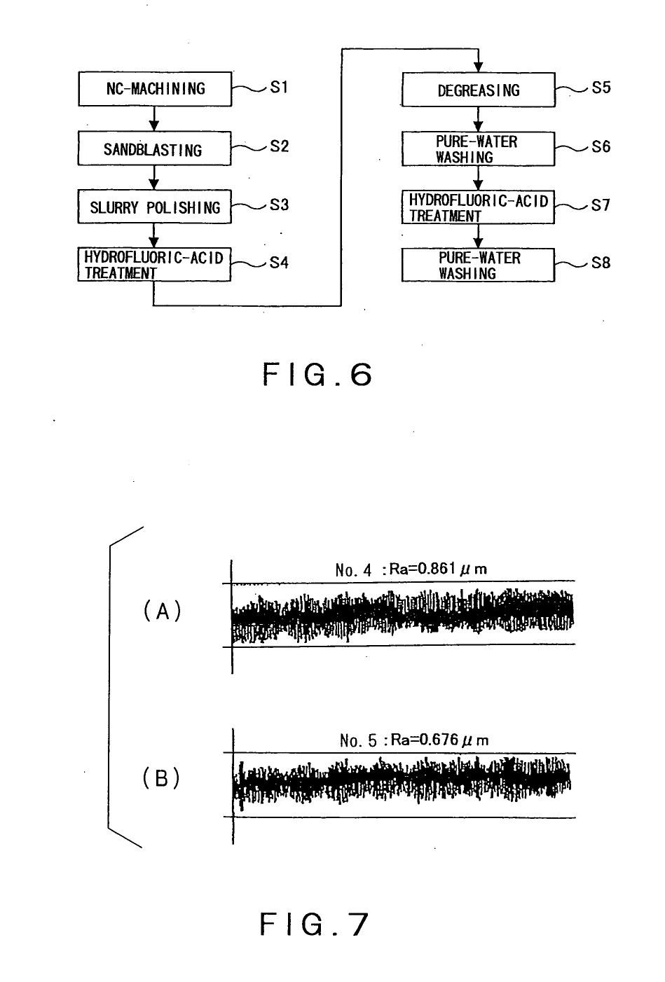

First, as shown in FIG. 6, the top plate (13) used in the plasma processing apparatus (10) made of quartz glass is manufactured by sequential execution of the following steps:
step S1 of machining a quartz glass plate into a desired shape by numerical control (NC) machining;
step S2 of performing sandblasting to the surface of the NC-machined quartz glass plate to reduce the thickness thereof to a predetermined thickness;
step S3 of performing slurry polishing to the sandblasted surface of the quartz glass plate;
step S4 of performing hydrofluoric acid treatment to the slurry-polished surface of the quartz glass plate;
step S5 of degreasing the hydrofluoric-acid-treated surface of quartz glass plate;
step S6 of washing the degreased surface of the quartz glass plate surface with pure water;
step S7 of performing hydrofluoric acid treatment to the water-washed surface of the quartz glass plate surface; and
step S8 of washing the hydrofluoric-acid-treated surface of the quartz glass plate surface in pure water.

Meanwhile, the top plate (304) according to the present invention is manufactured as follows:

### [If Mechanical Polishing is Used]

Polishing using a polishing agent of potassium oxide particles is conducted between the foregoing steps S3 and S4, thereby to improve surface roughness significantly. Other steps may be substantially the same as in FIG. 6.

### [If Fire Polishing is Used]

After step S1, a hydrofluoric acid treatment step a degreasing step, and a pure-water washing step (these steps are the same as foregoing steps S3, S4, and S5, respectively) are performed, and then a drying step is further performed. Thereafter, a fire polishing treatment is performed. Then, an annealing treatment is performed for one hour at 1000° C. to remove strain. Thereafter, the aforementioned hydrofluoric acid treatment step and the pure-water washing step (these steps in the second cycle are the same as foregoing steps S7 and S8 respectively) are performed.

The aforementioned hydrofluoric acid treatment may be conducted by immersing the quartz glass plate in a 1% to 10% concentration of hydrofluoric acid bath for 1 to 5 minutes, for example.

Top plates were actually manufactured using the above conventional process and the process of the present invention, and film-forming experiments were conducted using those top plates. The following describes the experimental results.

FIGS. 7(A) and 7(B) show measurement results on surface roughness of a surface, which is to face the substrate W, of each of the quartz glass top plates obtained using the conventional process. As shown in FIGS. 7(A) and 7(B), each quartz glass top plate formed using the conventional process had surface roughness ranging from 0.6 to 0.9 μm in arithmetic mean roughness Ra. Although the surface visually appeared to be flat and smooth, depressions and projections were present thereon actually. In the example of FIG. 7(A), Ra was 0.861 μm (Sample 4); and in the example of FIG. 7(B), Ra was 0.676 μm (Sample 5).

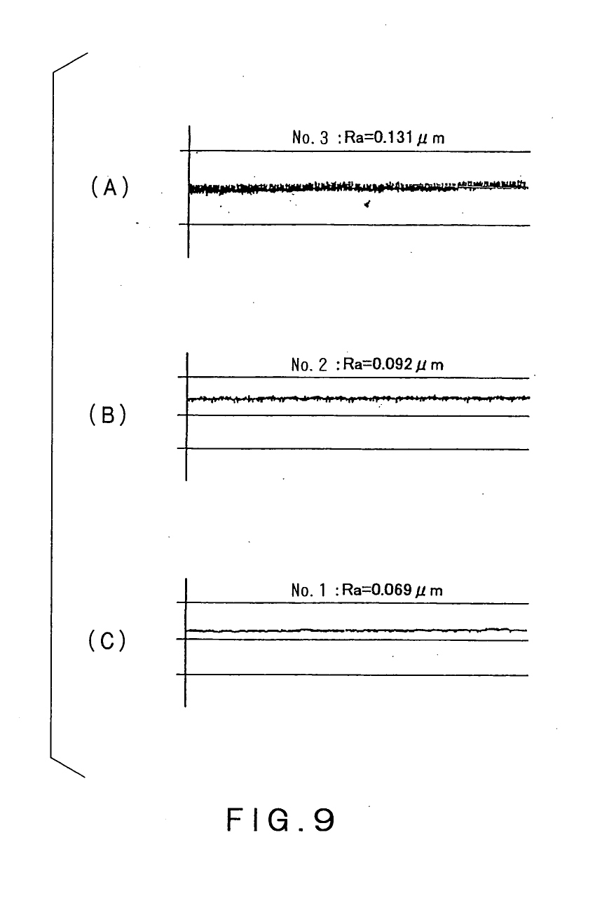

FIG. 9(A) shows the measurement result (Sample 3: Ra=0.131 μm) of the surface roughness of the top plate 304 made of a quartz glass, which was subjected to mechanical polishing according to the manufacturing method of the present invention. FIG. 9(B) shows the measurement result (Sample 2: Ra=0.092 μm) of the surface roughness of the top plate 304 that was subjected to fire polishing according to the manufacturing method of the present invention. FIG. 9(C) shows the measurement result (Sample 1: Ra=0.069 μm) of the surface roughness of the top plate 304 that was subjected to fire polishing according to the manufacturing method of the present invention.

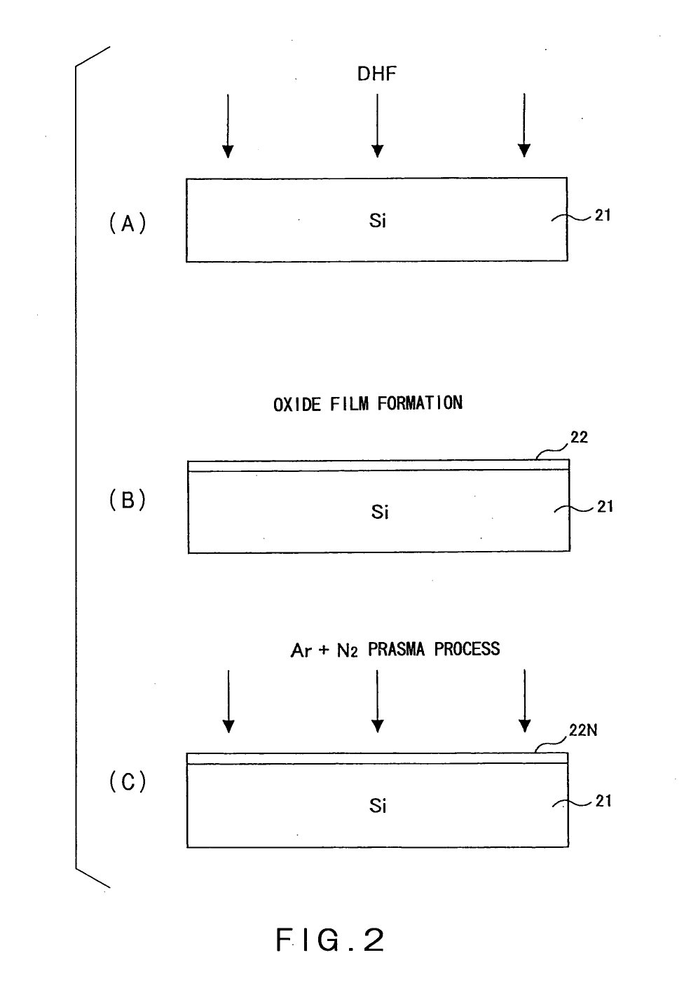

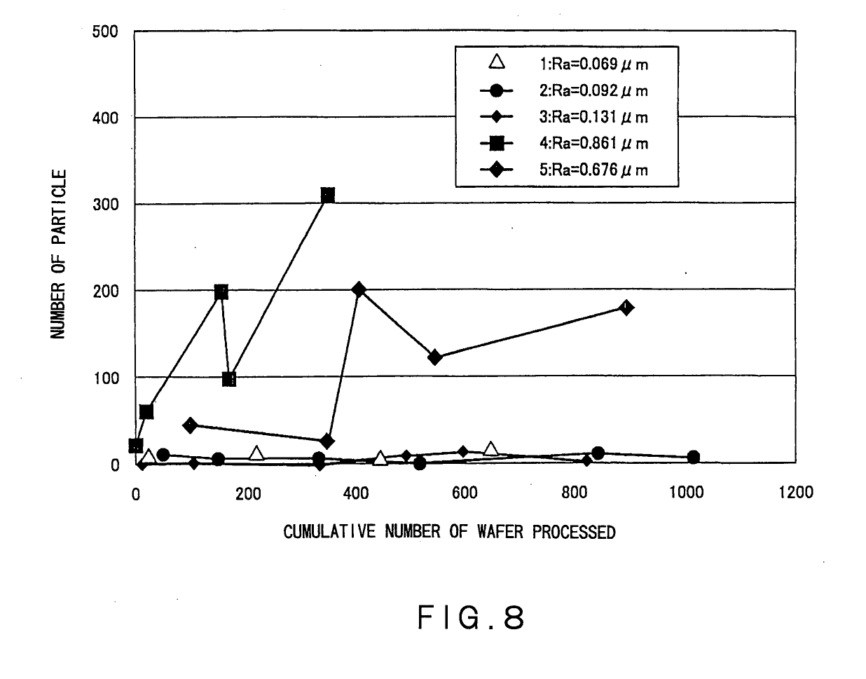

Film-forming experiments were conducted using the microwave plasma processing apparatus (300) employing the foregoing quartz glass plates as the microwave-transmitting top plate (304). The oxynitriding process shown in FIGS. 2(A) to 2(C) was performed to each substrate for 20 seconds by supplying microwaves at a power of 1500 W while supplying Ar gas and nitrogen gas at flow rates of 1000 sccm and 40 sccm, respectively, under a pressure of 6.65 Pa (50 mTorr). The substrate temperature was 400° C. Substrates were randomly sampled from a large number of sequentially processed ones, and particles present on each sampled substrate were counted using a laser microscope. FIG. 8 is a graph representing the number of particles of 0.16 μm or more in diameter that were observed on the surface of the processed substrate W. It should be noted that the generally accepted maximum permissible count of particles having a diameter of 0.16 μm or more is 20, at present.

As can be seen from the graph of FIG. 8, when the quartz glass plates manufactured in the conventional process of FIG. 6, one of the glass plates being 0.861 μm in Ra (Sample 4, marked as ▪) and the other being 0.676 μm in Ra (Sample 5, marked with a larger ♦), were used as the top plate 304, the particle count abruptly increased with increasing of the cumulative number of wafer processed.

In contrast, it can be seen that, with the top plates 304 (Samples 1 to 3) manufactured using the foregoing manufacturing method of the present invention, particle counts were dramatically decreased. That is, it can be seen that, if the surface roughness of the face of the quartz glass top plate 304 facing the substrate is controlled below 0.2 μm in arithmetic mean surface roughness Ra, even if the plasma process to the substrate W is performed under a low process pressure of 26.6 Pa (200 mTorr) or less, occurrence of particles on the surface of the substrate W can be dramatically suppressed.

It is evident from the relationship between the surface roughness of the top plate 304 and the particle count that the surface condition of the quartz glass top plate 304 affects the generation of the particles. Considerations on the reason for this are discussed below.

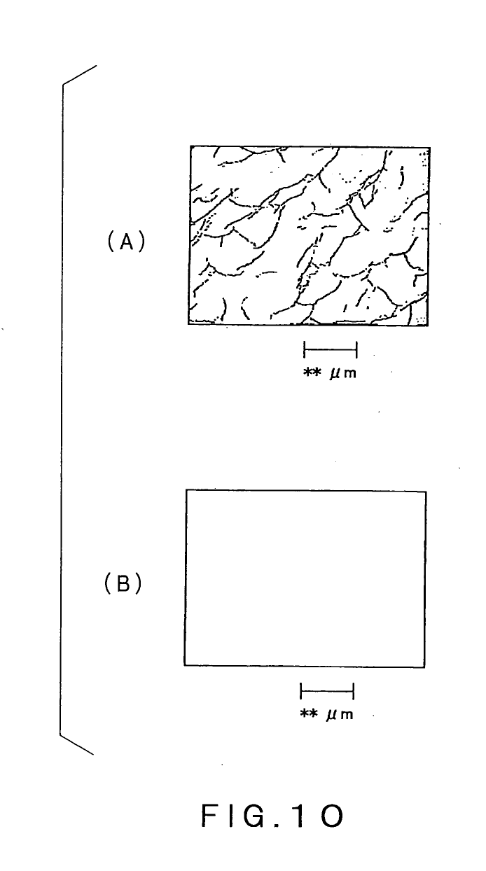

FIG. 10(A) is a copy of an optical micrograph showing the surface condition of the quartz glass top plates 304 manufactured by the conventional method shown in FIG. 6. As is evident from this micrograph, a number of microcracks are present on the surface of the top plate 304, and it is considered that those microcracks may possibly cause increasing of the surface roughness, although it is not confirmed at present. It is considered that such microcracks were introduced into the quartz plate constituting the top plate in the NC-machining step S1 and the sandblasting step S2 of the top-plate manufacturing process shown in FIG. 6, and the maximum depth of the cracks is considered to be several hundreds of microns.

FIG. 10(B) is a copy of an optical micrograph showing the surface condition of the quartz glass top plate 304 created using the foregoing process, inclusive of fire polishing, of the present invention. As is evident from this micrograph, microcracks that were exposed on the surface of the top plate 304 disappeared by fire polishing.

The surface condition shown in FIG. 10(B) corresponds to data of Sample 1 or 2 marked with Δ or in the graph of FIG. 8. Based only on those data, it is considered that the generation of particles in those samples was suppressed due to the disappearance of the microcracks on the surface of the top plate. It is also considered that the decreasing of the surface roughness is due to the disappearance of the microcracks.

However, since Sample 3 in FIG. 9(A), which corresponds to data marked with a smaller ♦ in the graph of FIG. 8, was subjected to mechanical polishing. Thus, it is considered that, even though the surface roughness Ra of the quartz glass top plate was 0.131 μm, microcracks were present on the surface of the top plate. In this case, however, it is apparent from FIG. 8 that the generation of particles was suppressed. It is deduced, therefore, that the quantity of generated particles does not depend only on whether or not microcracks are present on the surface.

Anyway, it is concluded from the above experiments is that, if the surface roughness of the surface of the top plate facing the substrate W reduced to 0.2 μm or less in arithmetic mean surface roughness Ra according to the present invention, the generation of particles can be effectively suppressed during a plasma process, and more particularly during a plasma process under a low pressure of 26.6 Pa (200 mTorr) or less.

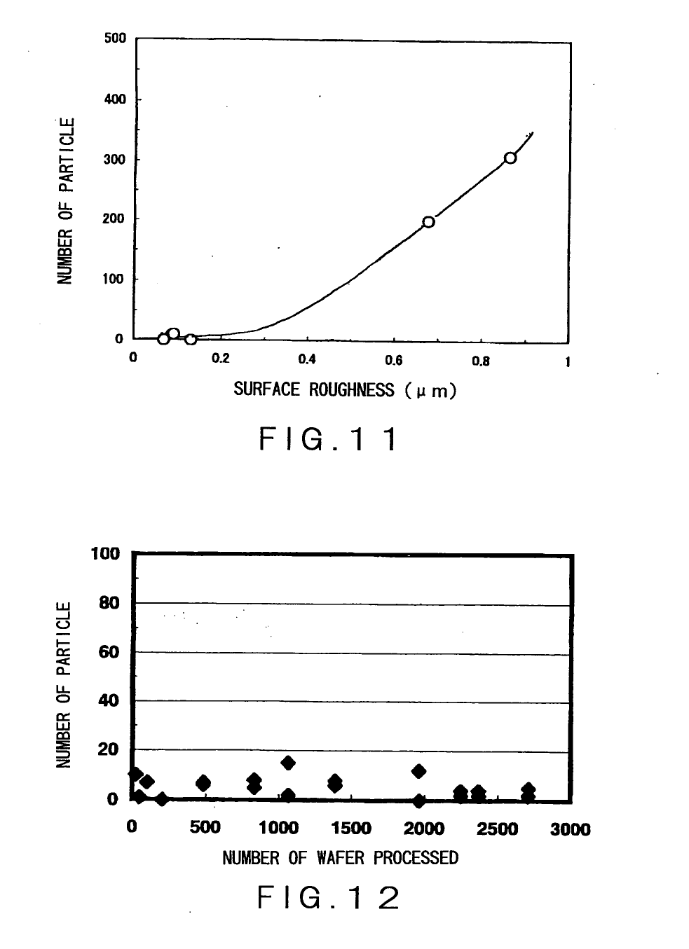

For a better understanding of the above, FIG. 11 is provided. FIG. 11 is a graph representing the relationship between the surface roughness and the particle count; the data in the graph of FIG. 11 are extracted from the data plotted on the graph of FIG. 8 (the extracted data corresponds to the cumulative number of the processed wafers from 100 to 200). Hence, it can be understood that, if the surface roughness Ra is 0.2 μm or less, the particle count is significantly reduced. It can also be understood that, if the surface roughness Ra is 0.13 μm or less, the particle count is further reduced.

FIG. 12 is a graph showing the results of the endurance test of the quartz glass top plates 304 manufactured by using the foregoing manufacturing method (using fire polishing) according to the present invention. The endurance tests were conducted on a plurality of top plates having surface roughness Ra ranging from 0.03 μm to 0.1 μm. Through the test, it was confirmed that, if the surface roughness Ra was 0.1 μm or less, long-term durability of the top plate was achieved.

While the present invention has been described above based on the preferred embodiments thereof, the invention is not limited to such particular embodiments and can incorporate various modifications and changes within the gist of the invention, described in the appended claims. For example, as denoted by an alternate long and short dash line in the top plate 304 of FIG. 3, a circular recess having a diameter slightly greater than that of the substrate can be provided in the lower surface of the top plate 304. Such a recess contributes to suppression of standing waves. Only the bottom face of the recess may have the aforementioned surface roughness. In addition, the substrate is not limited to a semiconductor wafer, and may be an LCD substrate, for example.

1. A microwave plasma processing apparatus, comprising:
a processing container configured to be evacuated and having therein a substrate mounting table to hold a substrate;
a top plate made of quartz glass, the top plate being disposed at an upper portion of the processing container so as to face the substrate held on the substrate mounting table;
a microwave antenna provided above the top plate; and
a gas supply system that supplies a process gas into the processing container;
wherein a surface, facing the substrate, of the top plate has surface roughness equal to or less than 0.2 μm in arithmetic mean roughness Ra.

2. The microwave plasma processing apparatus according to claim 1, wherein the surface, facing the substrate, of the top plate has surface roughness equal to or less than 0.13 μm in arithmetic mean roughness Ra.

3. The microwave plasma processing apparatus according to claim 1, wherein the surface, facing the substrate, of the top plate has surface roughness equal to or less than 0.1 μm in arithmetic mean roughness Ra.

4. The microwave plasma processing apparatus according to claim 1, wherein the surface, facing the substrate, of the top plate is subjected to fire polishing.

5. The microwave plasma processing apparatus according to claim 1, wherein the surface, facing the substrate, of the top plate is subjected to mechanical polishing.

6. The microwave plasma processing apparatus according to claim 1, wherein a circular recess is formed in the surface, facing the substrate, of the top plate, and wherein a bottom face of the recess has surface roughness equal to or less than 0.2 μm in arithmetic mean roughness Ra.

7. A top plate formed of quartz glass for transmitting therethrough microwaves to deliver microwave radiation to an interior of a processing container,
wherein a surface of the top plate, which is to be exposed to an interior space of the processing container when the top plate is mounted to the processing container, has surface roughness equal to or less than 0.2 μm in arithmetic mean roughness Ra.

8. The top plate according to claim 7, wherein the surface roughness of the top plate is equal to or less than 0.13 μm in arithmetic mean roughness Ra.

9. The top plate according to claim 7, wherein the surface roughness of the top plate is equal to or less than 0.1 μm in arithmetic mean roughness Ra.

10. The top plate according to claim 7, wherein the surface of the top plate, which is to be exposed to the interior space of the processing container, is subjected to fire polishing.

11. The top plate according to claim 7, wherein the surface of the top plate, which is to be exposed to the interior space of the processing container, is subjected to mechanical polishing.

12. The top plate according to claim 7, wherein a circular recess is formed in the surface of the top plate, which is to be exposed to the interior space of the processing container, and wherein a bottom face of the recess has surface roughness equal to or less than 0.2 μm in arithmetic mean roughness Ra.
